(19) United States
(12) Patent Application Publication
(10) Pub. No.: US 2006/0051522 A1
(43) Pub. Date: Mar. 9, 2006

(54) Method of pulsed laser assisted surface modification

(76) Inventor: James D. Talton, Gainsville, FL (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/502,022

(22) PCT Filed: Jan. 22, 2003
(86) PCT No.: PCT/US03/00040

§ 371 Date: Oct. 12, 2005

Related U.S. Application Data
(60) Provisional application No. 60/349,557, filed on Jan. 22, 2002.

(51) Int. Cl. B05D 3/00; C23C 14/30; C23C 16/00

(52) U.S. Cl. 427/596; 427/561; 118/723 R; 118/726

(57) ABSTRACT

A method comprising providing a target material (115), providing a substrate (107), ablating the target material (115) to form ablated target particulate material (117), directing the ablated particulate material (117) toward the substrate (107) with a gas flow, and coating the substrate surface (107).

The present application claims priority under 35 U.S.C. § 119 to U.S. Provisional Patent Application No. 60/349,557, filed Jan. 22, 2002.

### BACKGROUND OF THE INVENTION

1. Field of the Invention

The invention relates to processes for changing the surface properties and/or applying a thin coating to surfaces of a substrate, such as biomedical devices or sensing surfaces that improve surface interactions in gaseous, liquid, or biological environments and devices produced thereby. The substrate may include, but is not limited to, an optical, electronic, or acoustic gas sensor, a microfluidic biosensor or microarray, and a partially or wholly implanted device or any external device in contact with biological fluids and/or surfaces. More particularly, the invention provides new methods for preparing compositions that are coated with ultrafine layers of coating material, such as organic polymeric coating materials, applied through a non-aqueous, non-solvent technique near atmospheric pressure. In one embodiment, the process is a vapor deposition process such as pulsed laser ablation. Among the many advantages of the disclosed methods are control of both the thickness and uniformity of the coating on the substrate surface.

2. Description of Related Art

Several gamma irradiation (Goldberg, Burns et al. 1989), plasma treatment (Narayanan, Rowland et al. 1994), radio-frequency magnetron sputtering (Ruckenstein and Gourisankar 1986), dip-coating (Moussy, Kreutzer et al. 2002), and chemical modification techniques have been researched to produce biocompatible coatings onto medical devices such as stents, catheters, vascular grafts, contact lenses, ocular implants, oral implants, hip implants, pacemakers/defibrillators, and bonefixation devices, but these processes are limited by poor control of adhesion and composition, rigorous processing conditions, and long reaction times. Pulsed laser deposition (PLD) of ceramics at low pressure (400 mT) have also been described for implant applications (Cotell, Chrisey et al. 1993). Laser desorption at atmospheric pressure is well known as a method to introduce analytes for mass spectrometry (Coon and Harrison 2002; Coon, McHale et al. 2002), as well as laser etching without vacuum (Chang and Molian 1999). Although laser ablation of semiconductor materials and polymers at atmospheric pressure have been investigated (Whitlock and Frick 1994), only deposition of the ablated material, particularly at very low pressures (<1 Torr), which increase run-times to over an hour and require specialized vacuum equipment, has been described (U.S. Pat. No. 6,025,036).

A limitation of most surface modification systems, in general, is that multi-stage scale-up from the laboratory to commercial-scale production can be lengthy and difficult, often requiring specialized equipment and expensive solvents. Additionally, known systems typically produce surface coatings with poor control of the morphology and adhesion that compose undesirable properties. Therefore, what is needed are improved methods for preparing high-quality coatings that do not suffer these limitations, and that are useful in preparing products with superior surface properties of the final product.

### SUMMARY OF THE INVENTION

### A. Features and Advantages of the Invention

The present invention overcomes these and other inherent deficiencies in the prior art by providing novel coating methods for use in preparing coated substrates, in particular coated biomedical devices and sensors, having improved surface properties. In general, the methods disclosed herein provide a means for coating substrates with one or more layers of discrete coating matter or materials such that the coated matter or materials adheres generally uniformly to the surface of the substrate to form either continuous or discontinuous coatings depending upon the particular application of the coated device.

The described process has the advantages of producing highly uniform, ultra-thin coatings with controlled architectures while requiring minimal processing and equipment. Nanofunctional mesoscopic molecules may then be introduced easily which further change the surface properties of the coating and further improve the desired biological or sensor response. The flexibility of this procedure provides many processing parameters that change the coating thickness, uniformity, and improve long-term biocompatibility in vivo. The invention also provides methods for modification of the substrate's surface (1) morphology; (2) adhesion; (3) hydrophobicity; (4) inflammation; (5) infection; and (6) biological protein and tissue binding in vivo, by applying coatings using the methods of the present invention to greatly enhance the biological or desired response.

The process also has several advantages over current coating or surface modification techniques including:
1. It is a fast process with modification times on the order of minutes.
2. A variety of materials can be used for producing the coatings on the substrate, thus it is possible to produce films from materials with proven suitability and/or biocompatibility.
3. It can be a dry, solventless technique conducted under a sterile clean-room environment.
4. Additional biologically active molecules, such as drugs, proteins, ceramics, or other materials, may be applied as coatings during the process or applied/chemically-attached easily in a second step, i.e. protein attachment to a functionalized surface.
5. Laser ablation can be performed efficiently at or near atmospheric pressure, as opposed to other physical vapor deposition processes requiring high vacuum, thereby eliminating the need for large vacuum pumps and run-times of several hours. This advantage significantly improves production times, and thereby decreasing production costs and scale-up difficulty.

### B. Summary of the Invention

The present invention provides methods of coating a substrate surface, comprising: providing a target material; providing a substrate; ablating said target material to form ablated target particulate material; directing the ablated target particulate material toward the substrate with a gas flow; and coating said substrate surface with said ablated target particulate material to form a coated substrate. The coating may occur at a pressure of about 1 Torr or higher, including about about 760 Torr.

Coating may be achieved by applying a gas flow directed at the substrate at a flow rate of about 1 milliliter per minute or higher, including about 10 milliliters per minute or higher, and at a velocity sufficient to direct the ablated particulate material toward the substrate.

The target material includes at least a biodegradable polymer, biocompatible polymer, chemoselective polymer, polysaccharide, and/or protein. Ablating may be achieved by the use of a high energy source, which may be a laser. Lasers include, but are not limited to, ion laser, diode array laser, and pulsed excimer laser.

Coating the substrate with the ablated particulate target material may result in a coating of the target materials on the substrate of a thickness of less than about 1 mm. The coating on the core materials may have a thickness of less than about 0.1 mm, or less than about 0.01 mm.

The substrate may include at least one surface of a biomedical device selected from the group consisting of electronic gas sensors, acoustic gas sensors, microfluidic biosensors, microarrays, at least partially implanted devices, or external devices in contact with biological fluids and/or surfaces. The biomedical device may include stents, catheters, vascular grafts, contact lenses, ocular implants, oral implants, hip implants, pacemakers, defibrillators, and bone fixation devices. The sensor device may include metal-oxide sensors, conducting polymer sensors, electrochemical sensors, fiber-optic fluorescent sensors, and surface acoustic wave sensors. The coating of the target material on the substrate may result in a continuous coating or a discontinuous coating.

In other embodiments, the present invention includes methods of coating a substrate surface, the method comprising: providing a target material; providing a substrate; ablating said target material to form ablated target particulate material; directing the ablated target particulate material toward the substrate with a gas flow; and coating said substrate surface with said ablated target particulate material to form a coated substrate; wherein the coating occurs at a pressure of about 1 Torr or higher.

In other embodiments, the present invention includes a coating apparatus comprising: a coating chamber housing a target material in its interior; the chamber comprising a transparent window; a target evaporation source exterior to the coating chamber; a means for directing a gas flow toward the substrate.

The present invention also provides coated substrates formed according to these methods.

### BRIEF DESCRIPTION OF THE DRAWINGS

The drawings form part of the present specification and are included to further demonstrate certain aspects of the present invention. The invention may be better understood by reference to one or more of these drawings in combination with the detailed description of specific embodiments presented herein.

FIG. 1 is a general illustration of the top-coating method.

FIG. 2 is a general illustration of the bottom-coating method.

FIG. 3 is a general illustration of A) a substrate rotator and B) a substrate rotator mount for coating multiple substrates (¼″ probe ends).

FIG. 4 shows digital images of PLGA coating A) on a glass slide near (200× magnification) and B) through 80 mesh onto a glass slide (100× magnification).

FIG. 5 shows A) absorption spectra for the initial release of tetracycline into PBS from PLGA matrix coated onto cover slip and B) 7 day tetracycline release curve for PLGA/tetracycline (12.5%) coated sample.

FIG. 6 shows a digital image of A) PLA coating on a glass slide near atmospheric pressure (10 Torr) and B) PLA/HA (20%) coated sample with HA stained black with Von Kessa stain.

FIG. 7 shows the FTIR spectra of A) original PLA, B) deposited PLGA at 500 mJ/cm² near atmospheric pressure (10 Torr).

FIG. 8 shows glass slides placed in the middle of growing 293 human embryonic kidney cells with A) no coating (control) and B) PVP-coating displaying reduced adhesion and spreading.

FIG. 9 shows coated glass slides placed in the middle of growing E. coli with A) no coating (control) and B) PTFE-coating displaying reduced bacterial adhesion.

FIG. 10 shows E. coli adhesion to uncoated and PTFE-coated glass slides (+/−SD).

FIG. 11 shows SEM images of A) poly-epi-chloro-hydrin (PECH) coated areas on silicon wafers displaying scratch mark at 1,000 times magnification, and B) poly-iso-butylene (PIB) on silicon with scratch mark at 10,000 times magnification.

### DETAILED DESCRIPTION OF THE INVENTION

The invention is directed to improved methods of coating substrate materials at or near atmospheric pressure with a directed gas flow, and the coated substrate materials produced thereby. The present invention utilizes the discovery that the deposition of thin-films onto a substrate near atmospheric pressure is substantially improved utilizing a directed gas flow to enhance the exposure of a substrate to the ablated species. Substrates to be coated in accordance with this invention are those in which a thin coating is desirable. Such substrates include, but are not limited to, any biomedical device such as an electronic or acoustic gas sensor, a microfluidic biosensor or microarray, or a partially or wholly implanted device or any external device in contact with biological fluids and/or surface, as well as particles for which a thin coating is desirable. Of course, this invention is also applicable to the application of thin layers of active materials to a substrate. Examples might include biologically active coatings, such as antigens, nucleic acids, proteins, or even pharmaceuticals. The possibilities and combinations are numerous.

The invention is particularly directed to substrates in the form of biomedical implants and sensors coated with a material, which may be a biodegradable or biocompatible matter, including biodegradable or biocompatible polymers. The coating may impart a number of characteristics to the substrate, including altering its surface morphology, charge, wetability, adhesiveness/bioadhesion, inflammatory response, and long-term stability and response. Additional materials, such as drugs, proteins, or bioactive ceramics, may be incorporated which will further modify the desired biological or sensor response. If an additional material, such as a drug, to the coating material, such as a biodegradable polymer, the rate of diffusion and/or release of an active component may be modified by producing different compositions using the described process. Particularly, the invention provides methods for preparing substrate material compositions that are coated with ultrafine layers of coating materials, for example, organic polymeric coating materials, which are applied through a non-aqueous, non-solvent technique. On embodiment is a vapor deposition process using pulsed laser ablation. Among the many advantages of the disclosed methods are control of both the thickness and uniformity of the coating on the surface of the substrate, thus imparting direct control over the desired response.

### A. Methods for Preparing Coated Substrates

The methods of the present invention generally involve physical vapor deposition (PVD) of the polymer coating onto the surface of the substrate material. Techniques for achieving PVD are well-known in the art, and include such methods as thermal evaporation, sputtering, and laser ablation of a target material to produce a flux of coating particulate materials, which are then contacted with the core substrate material, and allowed to form a coating thereon. For example, one method is laser ablation. Laser ablation for coating particles under very low pressure is disclosed in WO 00/28969, as well as coating onto particles near atmospheric pressure in U.S. Pat. No. 6,406,745.

In this invention, PLD or pulsed laser ablation is used in the preparation of metal, glass, plastic, and other substrate materials having atomic to nanometric thick coatings that impart improved physical and/or biological properties to the resulting coated substrate. Coatings may also be applied to improve other non-biological characteristics, such as the chemoselective response of a vapor or liquid sensor or the stability of a device to harsh organic vapors. The present coating methods are particularly desirable, since the substrate is not subjected to conditions that would decompose, destroy, or alter the activity of the substrate material itself, such as high temperatures or corrosive solvents. The use of PLD also minimizes the thermal decomposition or denaturation of the coating material itself, and permits the deposition of the coating material onto substrates using a directed gas flow that may be maintained at ambient temperature and atmospheric pressure during the deposition process.

Through regulation of the physical parameters of the deposition process (including background gas flow, pressure, and coating exposure time) the skilled artisan may now for the first time prepare a variety of coated substrates that comprise ultrathin coatings. In particular, the method affords the control of both the extent of molecular coating, and the thickness of the resulting coating layer on the surfaces of a variety of substrates. Both relatively thick coating layers, and relatively thin coating layers may be produced by controlling the extent of laser ablation process and the exposure of the substrate to the laser ablated coating material.

By choosing a correct energy density, the target material for coating ablates in a cluster-like form that retains a majority of the characteristics of the target material. Generally, when the energy density (fluence) is increased, the ablation has more of an atomic character, and is composed of atoms that do not resemble the signature of the original material. In addition, by imparting a gas flow, the ablated nanoparticle clusters are directed to the substrate further improving the surface exposure to the ablated target material near atmospheric pressure. Additional conditions may include: (1) control of the target or substrate positioning, (2) control of the target or substrate temperature, (3) exposure of the target or substrate to particular gases compared to room air, (4) exposure of the target or substrate to an additional energy source (such as and ion beam or UV light), and/or (5) post-processing of the coated substrate, such as high temperature curing or further chemical modification, to produce the desired results.

Operating the coating process at approximate atmospheric pressure allows for more continuous production process. Rather than needing to apply a deep vacuum for coating, the process of the present invention, operated at near atmospheric pressure, allows for continuous processing. For example, uncoated substrates are transported into a coating chamber and coated using the present method, at or near atmospheric pressure. Room air or an inert atmosphere is maintained by constantly flowing a gas, such as helium, into the chamber in a particular orientation. The gas may be directed to increase the exposure of the substrate to ablated particulates and further recirculated or recycled after filtering and scrubbing. Example gases include helium, argon, nitrogen, etc. Alternatively, if desired, the gas stream may be heated or cooled or a more reactive gas may be included, or used alone.

The invention is operated such that the coating chamber has a pressure of around atmospheric pressure, which may be a pressure as low as about 10⁻⁸ Torr to as high as about 2500, or any pressure in between. Alternatively, the pressure in the coating chamber is greater than about 10⁻⁶, or 10⁻⁴, or 10⁻², or 1 Torr, alternatively greater than about 10 or 50 Torr, and alternatively greater than about 700 Torr. Alternatively, the pressure in the coating chamber is less than about 1000, alternatively less than about 900, and alternatively less than about 820. In one embodiment, the pressure in the coating chamber is about 760 Torr, or atmospheric pressure.

The invention is operated such that the coating chamber has a gas flow introduced, which may be at a flow of 1 milliliter per minute to as high as about 100 liters per minute for a circular coating area of 6 inches diameter across, or any flow in between for a coating chamber of proportional dimensions. In some embodiments, the gas flow is greater than about 5, or 10, or 50 milliliters per minute, alternatively greater than about 80 milliliters per minute, and alternatively greater than about 100 milliliters per minute.

In one embodiment, a gas flow is introduced towards the substrate that carries the ablated particles from the target to increase the exposure of the substrate surface. The gas stream is sufficient to increase the deposition rate, thus reducing the overall processing time. The plume of ablated material and subsequent coating efficiency is dependent on several processing conditions including the laser frequency and energy, pulse rate, target material absorbance at the particular wavelength, and other factors, is also directly related to the direction and rate of gas flow. It has been discovered that a gas flow directed in the same direction as the plume may be used to deposit coatings near atmospheric pressure at a substantially higher rate. In another embodiment, a gas flow directed against or at a different angle than the plume may be applied to reduce the rate of deposition, which may produce increased control over the process. Methods of introducing a directional gas flow include connection of an entry tube from a specific location in the chamber with a valve, use of a distributor plate, as well as attachment of a nozzle on or inside the coating chamber. One example of a nozzle assembly known in the art is for liquid spray applications, or the use of a venturi or two-fluid nozzle mixing two gases for specific applications.

### B. Apparatus for Coating Substrates

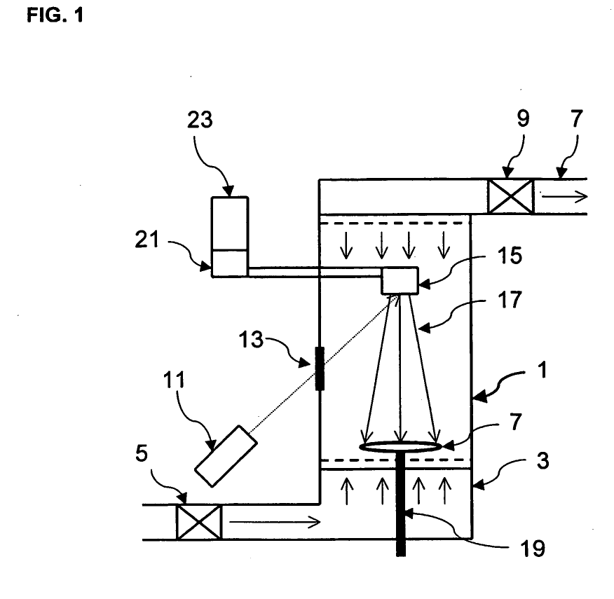

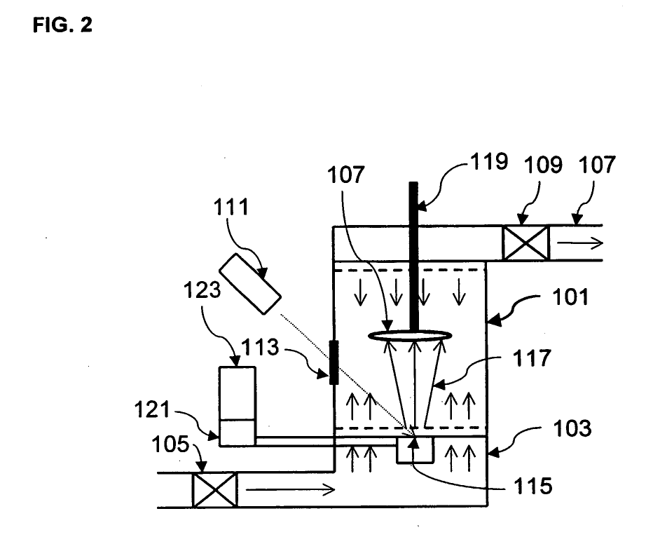

The process methodology is as explained below. FIGS. 1 and 2 show examples of the described methods. In general, the setup consists of a target and the substrate in the coating chamber. The external evaporation or removal source (EORS), such as a pulsed excimer laser, enters the chamber through a quartz window and interacts from a 45 degree angle above or below the matrix target (MT). A nanometer thin layer of the target material absorbs the energy from the laser pulse and the surface is rapidly heated and expands from the target in the form of a plume of ablated atomic, nanometer, and micrometer size particles. The plume of material is then deposited onto the substrate surface with a gas flow directed onto the surface to aid in the evaporation/coating process.

A region of target absorbs the incident energy, for example an excimer laser (wavelength=193-308 nm, energy=6.2-3.8 eV). The absorption depth of the incident laser depends on the chemical and physical structure of the target, typically the absorption depth will range from 10-100 nanometers. This rapid (nanoseconds) absorption and subsequent heating of the target surface by the laser pulse provides energy for desorption from the target material. Due to differential changes in the heated target in a time regime of nanoseconds, the matrix target ablates from the surface into a dense plume of atomic to micron-sized clusters, molecules and polymer chains. The plume of atomic to micron sized clusters, molecules, polymer and lipid fragments, and particles are then deposited onto substrate.

The MT described consists of a matrix of biocompatible and/or biodegradable coating material, and additionally mesoscopic molecules that modify surface interactions. Biocompatible coating materials used for in the MT may include polymers, proteins, sugars, lipids, and other biologically inactive materials. Nanofunctional molecules that modify the surface interactions may include bioactive ceramics, anionic or cationic polymers or lipids, antibodies, or antigens. The matrix target, in liquid or solid form, may be dispersed in a solvent that evaporates comparatively quickly on the substrate. The biomedical device may be a wholly implanted device or any external device in contact with biological surfaces, as well as a sensor.

Since the EORS (in this example, the laser system) and the processing chamber are separate, the process offers great latitude for varying the coating structure and thickness. Also, with the proper EORS choice, this process can conceivably be used to create coatings of many different materials on particulates. The composition of the coatings is strongly dependent on the laser processing parameters such as incident energy fluence (J/cm²), laser repetition frequency, fluidization gas pressure, fluidization gas molecular weight, target to substrate distance, and the optical absorption coefficient of the matrix target and components.

FIG. 1 shows one embodiment of the present invention. The apparatus of FIG. 1 is a top-coating apparatus 1 with an opposing gas flow. The central apparatus 1 is connected to a gas distributor 3, controlled by a valve 5 with optional temperature control. An exhaust duct 7 controlled by valve 9 carries gas out or optionally recirculates gas back through a filter assembly back to valve 5 before re-entering the chamber. Recirculation, filtration, and temperature control of the chamber gas are particular aspects of the present invention.

Top-coating apparatus 1 includes an external evaporation or removal source (EORS) 11, which is directed upward into central chamber 1 through window 13 to the matrix target (MT) 15 at approximately a 45° angle. Window 13 is formed from an optically transparent material, for example, quartz. The plume 17 leaves MT 15 downward opposing the gas flow toward the substrate 19 below MT 15. The plume 17 coats the substrate 7 surface.

An external control device 21 and container 23 are used to feed or turn MT 15, which may involve a rotating motor control and/or feeding tube. Container 23 may also include a chiller to freeze material for MT 15. The substrate 7 is positioned opposing the MT 15 in the chamber and may be either stationary, rotating, or otherwise axially controlled by positioner 20.

FIG. 2 shows another embodiment of the invention, a bottom-coating apparatus 101 with a carrier gas flow. The central apparatus 101 is connected to a gas distributor 103, controlled by a valve 105 with optional temperature control. An exhaust duct 107 controlled by valve 109 carries gas out or optionally recirculates gas back through a filter assembly back to valve 105 before re-entering the chamber. Recirculation, filtration, and temperature control of the chamber gas are described aspects of the present invention.

Bottom-coating apparatus 101 includes an external EORS 111, which is directed downward into central chamber 101 through window 113 to the MT 115 at approximately a 45° angle. The plume 117 leaves MT 115 upward along the gas flow toward the substrate 107 below MT 115. The plume 117 coats the substrate 107 surface.

An external control device 121 and container 123 are used to feed or turn MT 115, which may involve a rotating motor control and/or feeding tube. Container 123 may also include a chiller to freeze material for MT 115. The substrate 119 is positioned opposing the MT 115 in the chamber and may be either stationary, rotating, or otherwise axially controlled by positioner 120.

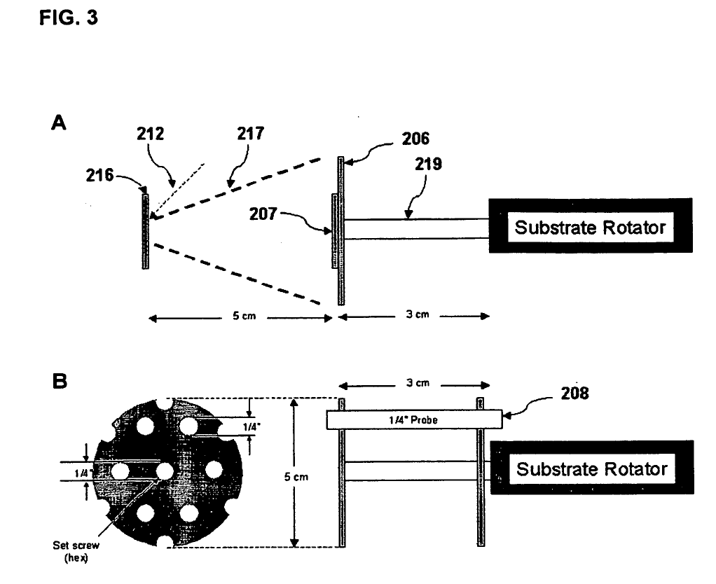

FIG. 3 shows yet another embodiment of the invention, a substrate positioner 219 with an attached substrate bracket 206. The EORS 212 generates a plume 217 that leaves MT 216 toward the substrate 207 attached to substrate bracket 206. Alternatively, multiple samples 208 may be mounted on substrate bracket 206 and coated simultaneously by rotating in front of the plume or at a 450 or 900 angle to coat samples 208 in any desired fashion.

In one embodiment, and as shown in FIGS. 1, 2, and 3, the PVD technique known as laser ablation is employed in the fabrication of the coated substrate. When desirable, other PVD techniques, such as thermal evaporation or sputtering, may be utilized to produce a flux of ablated species for deposition onto a host surface. A typical laser used in the practice of the present method is a Lambda Physik model 1248 pulsed excimer gas laser with an operating UV wavelength of 248 nanometers. Many other suitable lasers may be substituted, therefore, such as a Nd:YAG laser operating at 255-1064 nm, carbon dioxide lasers operating at wavelengths above 1 micron, etc. The laser beam will produce a particle flux generally perpendicular to the surface of the target.

### C. Coated Substrate Compositions

The coating techniques described herein and the compositions derived therefrom are applicable to a wide variety of compositions, including, but not limited to, an optical, electronic, or acoustic gas sensor, a microfluidic biosensor or microarray, and a partially or wholly implanted device or any external device in contact with biological fluids and/or surfaces. The present invention overcomes many of the disadvantages associated with the prior art. Coated substrate compositions of the present invention include discontinuous and continuous layers of particles on the outer surface of a substrate. Coated substrates, according to the described invention, are adherent and flexible in nature and cracking of the surface is avoided because the particles may be discrete and free to flex with the underlying substrate. In contrast, implants and coatings subject to other processes, such as dip coating and plasma spraying, may produce poor adhesion and tend to crack. It has unexpectedly been found that compositions in accordance with the present invention have superior surface bonding and flexibility, and thus avoid such disadvantages.

Examples of such medical devices include, but are not limited to, wholly-implanted devices, e.g., stents, grafts, oral implants, ocular implants, hip implants, pacemakers/defibrillators, and bone fixation devices, as well as those having some type of connective interface between the body of a mammal, in particular a human, and the outside environment, e.g., as percutaneous drain tubes, artificial ear implants, electrical connections, cannulas, and subcutaneous peritoneal dialysis catheters, etc. A material that has improved soft tissue bonding could be coated onto these medical devices, thus improving the long-term safety and efficacy.

Examples of such biomedical sensors include, but are not limited to, metal-oxide sensors (MOS), conducting polymers/electrochemical sensors (CP/EC), fiber-optic fluorescent sensors (FOFI), and surface acoustic wave sensors (SAW). In particular, surface acoustic wave (SAW) sensors are constructed with interdigital metal electrodes fabricated on piezoelectric substrates both to generate and to detect surface acoustic waves. Surface acoustic waves are waves that have their maximum amplitude at the surface and whose energy is nearly all contained within 15 to 20 wavelengths of the surface. Because the amplitude is a maximum at the surface such devices are very surface sensitive. SAW chemical sensors take advantage of this surface sensitivity to function as sensors. If a SAW device is coated with a thin polymer film it will affect the frequency and insertion loss of the device. If the device with the chemo-selective polymer coating is then subjected to chemical vapors that absorb onto the surface (based on an aromatic compounds affinity to the polymer), then the frequency and insertion loss of the device changes. It is this final change from baseline that allows the device to function as a chemical sensor. The polymer is normally chosen so that each will have a different chemical affinity for a variety of organic chemical classes, i.e., hydrocarbon, alcohol, ketone, oxygenated, chlorinated, and nitrogenated.

The target materials used for the coating include most solids currently used in the medical device and pharmaceutical industries, namely any material that can be effectively ablated by the energy source. These materials include, but are not limited to, biodegradable and biocompatible polymers, polysaccharides, proteins, ceramics, metals, and mixtures thereof. Suitable biodegradable polymers include polylactides, polyglycolides, polycaprolactones, polydioxanones, polycarbonates, polyhydroxybutyrates, polyalkylene oxalates, polyanhydrides, polyamides, polyesteramides, polyurethanes, polyacetates, polyketals, polyorthocarbonates, polyphosphazenes, polyhydroxyvalerates, polyalkylene succinates, poly(malic acid), poly (amino acids), polyvinylpyrrolidone, polyethylene glycol, polyhydroxycellulose, polyorthoesters, and combinations thereof, as well as other polylactic acid polymers and copolymers, polyorthoesters, and polycaprolactones, etc. Suitable biocompatible polymers include polyethyleneglycols, polyvinylpyrrolidone, polyvinylalcohols, polyacrylates, silicones, teflon, etc. Suitable polysaccharides include dextrans, cellulose, xantham, chitins and chitosans, etc. Suitable proteins include polylysines and other polyamines, collagen, albumin, etc. Suitable ceramics include calcium phosphates, calcium sulfates, bioactive glasses, etc. Suitable metals include stainless steel, cobalt-chromium, titanium, zinc, calcium, etc. A number of materials particularly useful as coating materials are disclosed in U.S. Pat. No. 5,702,716.

### D. EXAMPLES

The following examples are included to demonstrate example embodiments of the invention. It should be appreciated by those of skill in the art that the techniques disclosed in the examples which follow represent techniques discovered by the inventors to function well in the practice of the invention, and thus can be considered to constitute relevant examples for its practice. However, those of skill in the art should, in light of the present disclosure, appreciate that many changes can be made in the specific embodiments which are disclosed and still obtain a like or similar result without departing from the spirit and scope of the invention.

### Example 1

Biodegradable PLGA Coatings

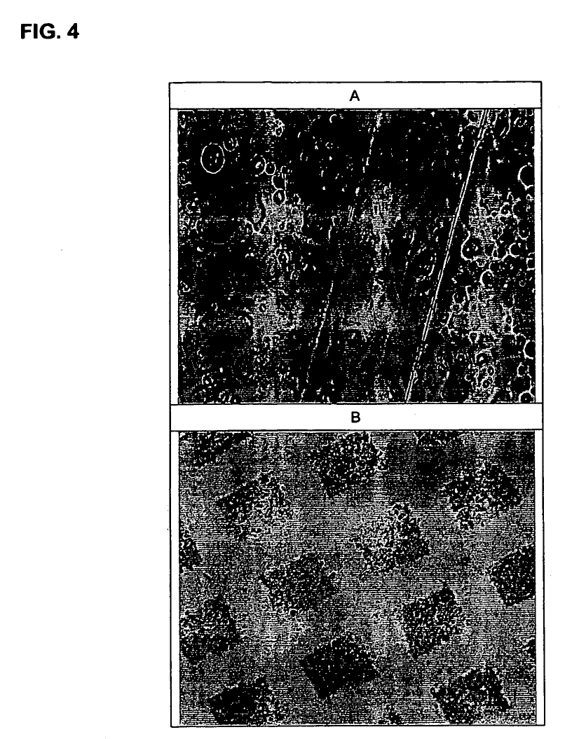

A coating of poly(lactic-co-glycolic acid) (PLGA) onto glass slides was produced in accordance with the present invention. PLGA is a resorbable polymer widely used in sutures and injectable drug delivery. A PLGA target was prepared by heating 4.0 grams of PLGA pellets (Lactel 50:50 DL, BPI, IV=0.59, Lot#D01 070) to 110° C. 1 inch metal die for 45 minutes and pressed at 5,000 psi in a Carver press for 30 minutes, allowed to cool to room temperature. The circular target was placed onto a target rotator at the bottom of the coating chamber and a glass slide was fixed on an opposing substrate rotator at the top at a distance of 3 cm from the target. Additional coatings were performed placing 80-mesh mask onto the glass slide to demonstrate the ability of coating defined areas. The chamber was purged to 5 Torr and helium or room air introduced into the chamber from below at 80 to 500 milliliters per minute for several runs with a resulting pressure of 5 to 500 Torr, as well as atmospheric pressure. The coating run was performed using a 248 nm KrF excimer laser (Lambda Physik L1000) at laser energies of 150 to 600 mJ/cm² at a pulse rate of 5 to 40 hertz for 1 to 5 minutes. Similar runs without the gas assist near atmospheric pressure did not produce visible coatings after 20 minutes. At the end of the run room air was introduced and the substrate removed. The coated samples were observed using an Olympus BH-1 microscope at 40 to 400 times magnification and 1 to 10 micron thick polymer films were observed as shown in FIG. 4A for continuous coatings (scratch shown to measure thickness) and FIG. 4B for discontinuous coatings.

### Example 2

Surface Modification with Tetracycline in PLGA Scaffold

A coating of 12.5% tetracycline, USP in poly(lactic-co-glycolic acid) (PLGA) was produced onto round glass slide coverslips under similar conditions as Example 1. Tetracycline-loaded resorbable membranes (Webber, Lago et al. 1998) and fibers (Norkiewicz, Breault et al. 2001) have been investigated for local delivery to prevent bacterial growth following periodontal surgery. In addition, bioceramic coatings onto catheters has also been proposed as a method of reducing bacterial attachment (Zabetakis, Cotell et al. 1995). In this example, a PLGA target was prepared by heating 3.5 grams of PLGA (Lactel 50:50 DL, BPI, IV=0.59, Lot#D01070) to 1000° C. in a glass beaker on a hotplate and adding 0.5 gram of tetracycline powder, USP (Spectrum Laboratories, Lot#QW039), mixing with a glass stir bar. The mixture was poured into a 1 inch metal die and allowed to cool to room temperature. The circular target was placed onto a target rotator at the bottom of the coating chamber and a glass slide was fixed on an opposing substrate rotator at the top at a distance of 3 cm from the target. The chamber was purged to 5 Torr and room air introduced into the chamber from below at 200 milliliters per minute with a resulting pressure of 50 Torr. The coating run was at laser energy of 450 mJ/cm² at a pulse rate of 10 hertz for 1 minute, producing a yellow spot (tetracycline coloration) on the glass slide and appeared microscopically similar to Example 1.

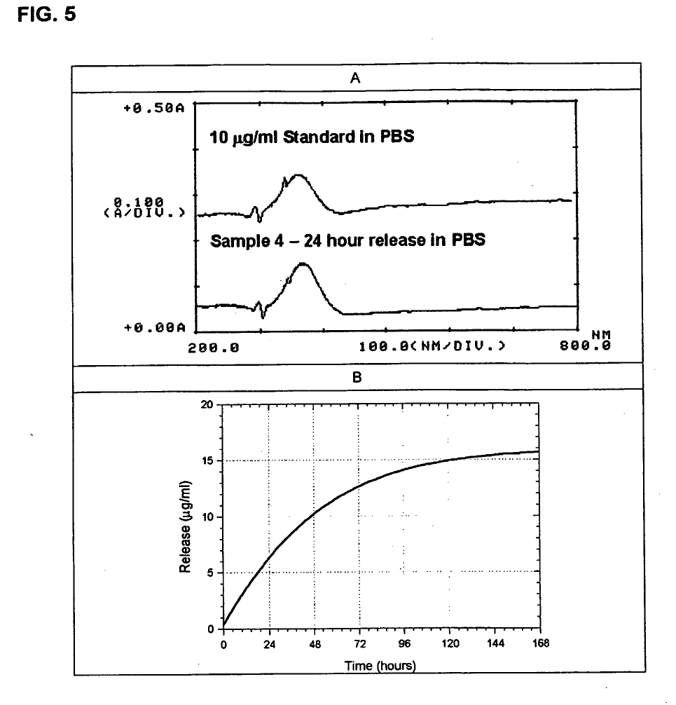

Biodegradable coatings containing tetracycline (or other antibiotics) have been proposed as a local delivery system to modulate the rate of release resulting in smaller dosages and less frequent administration (Mombelli, Schmid et al. 2002; Pataro, Franco et al. 2003). To measure the release-rate of tetracycline from coated substrates, similar runs were performed on four 1-inch circular glass slide cover slips (rotating) for 20 minutes at 10 hertz (12,000 pulses) and weighed, displaying an average coating weight of 1.3 mg (approx. 0.1 μg/pulse). Coated cover slips were then placed in the center of plastic petri dishes with 10 ml phosphate buffered saline (pH 7.4, 10 mM) placed on an orbital shaker at 6 RPM. Samples were measured using a Shimadzu UV160U UVN is spectrometer at 360 nm up to one week compared to 5 standards (0, 5, 10, 50, and 100 mg/ml). The absorbance spectras of the tetracycline released after 2 hours in buffer compared to standard (10 μg/ml) were similar (normal absorbance below 300 nm not observed from absorbance of plastic sample cuvets). The spectras and average release curve up to one week for the release of tetracycline from PLGA (n=4) are shown in FIGS. 5A and 5B, respectively.

### Example 3

Biodegradable PLA Coatings

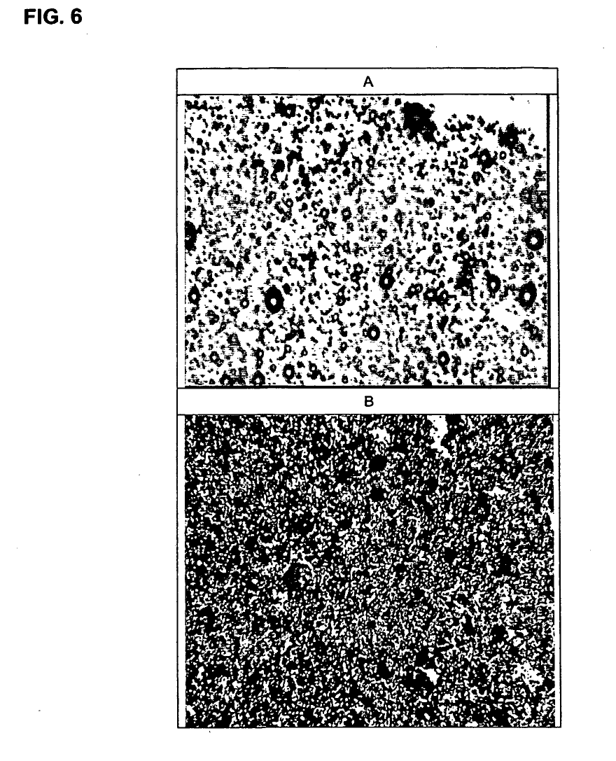

A coating of poly(1-lactic acid) (PLA) was produced onto a glass slide under similar conditions as Example 1. The target was prepared by heating 4.0 grams of PLA (Medisorb, PLA Methyl Ester 100L, Lot#00-141-5) to 140° C. in a 1 inch metal die for 45 minutes and pressed at 5,000 psi in a Carver press for 30 minutes, allowed to cool to room temperature. The circular target was placed onto a target rotator at the bottom of the coating chamber and a glass slide was fixed on an opposing substrate rotator at the top at a distance of 3 cm from the target. The chamber was purged to 5 Torr and helium or room air introduced into the chamber from below at 80 to 500 milliliters per minute for several runs with a resulting pressure of 5 to 500 Torr, as well as atmospheric pressure. The coating run was performed at laser energies of 150 to 600 mJ/cm² at a pulse rate of 5 to 40 hertz for 1 to 5 minutes. At the end of the run room air was introduced and the substrate removed. The coated samples were observed using a Olympus BH-1 microscope at 100 times magnification and 1 to 10 micron thick polymer films were observed as shown in FIG. 6A.

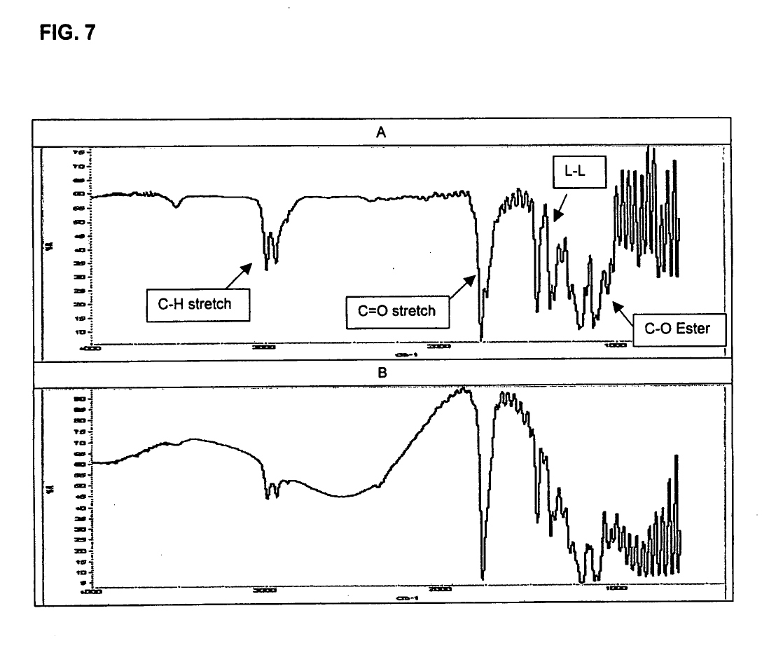

Fourier-transform infrared spectroscopy (FTIR) was also used to characterize the polymer structure using a Nicolet Magna 760 FTIR with OMNIC 3.0 software and shown in FIG. 7. Reflectance of films were monitored using the microscope attachment, subtracting spectra for uncoated substrates. For comparison with original polymer analysis, 10 mg of polymer was dissolved in 2 ml of methylene chloride and cast on a glass slide and the solvent evaporated. Characteristic absorptions peaks seen in both profiles are a C═O stretch carbonyl peak at 1,760 cm⁻¹, C—H stretch methyl peak (from lactide) at 2,850 cm⁻¹, and carboxylate peak at 1650 cm⁻¹. Ester peaks are present corresponding to monomeric units within the polymeric chain of lactide-lactide (L-L) at 1456 cm⁻¹ and for the C—O single bond at 1,000-1,300 cm⁻¹. In general, the spectra of deposited PLA samples retained similar characteristic peaks to original PLA suggesting deposited polymer films were intact PLA.

### Example 4

Surface Modification with Hydroxyapatite in PLA Scaffold

A coating of 20% hydroxyapatite (HA) in poly(1-lactic acid) (PLA) was produced onto a glass slide under similar conditions as Example 3. Coarse calcium phosphate/hydroxyapatite coatings onto hip implants and bone fixation devices using plasma and thermal spray techniques are well known, and more controlled polymer/hydroxyapatite coatings have also been described recently (Weng, Wang et al. 2002). In this example, the target was prepared by heating 4.0 grams of PLA (Medisorb, PLA Methyl Ester 100L, Lot#00-141-5) to 100° C. in a glass beaker on a hotplate and adding 1.0 gram of HA powder (10 microns), mixing with a glass stir bar. The mixture was poured into a 1-inch metal die and allowed to cool to room temperature. The circular target was placed onto a target rotator at the bottom of the coating chamber and a glass slide was fixed on an opposing substrate rotator at the top at a distance of 3 cm from the target. The chamber was purged to 5 Torr and room air introduced into the chamber from below at 200 milliliters per minute with a resulting pressure of 50 Torr. The coating run was at laser energy of 450 mJ/cm² at a pulse rate of 10 hertz for 1 minute, producing a white spot on the glass slide. The results are shown in FIG. 6B, with the calcium phosphate crystals on the surface of the scaffolds visualized by Von Kossa stain.

### Example 5

Hydrogel PVP Coatings

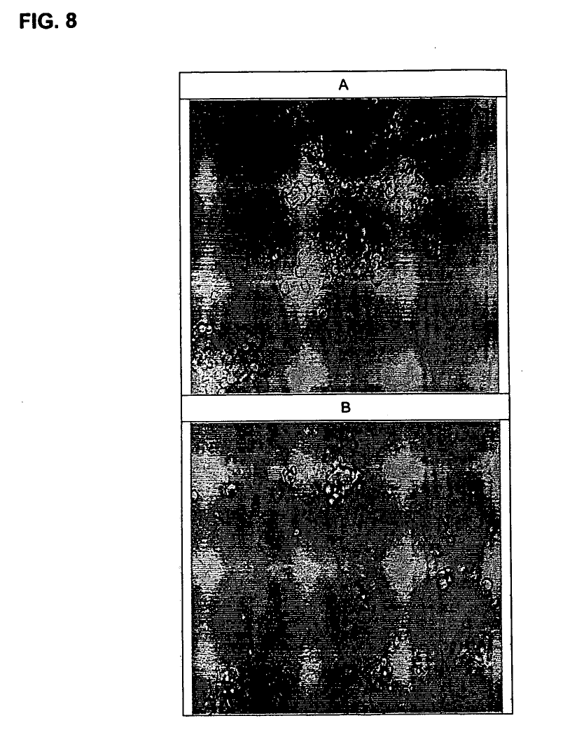

A coating of poly(vinyl pyrollidone) (PVP) onto glass slides was produced in accordance with the present invention. PVP coatings have been previously proposed to reduce cell adhesion to dialysis membranes (Higuchi, Shirano et al.) because of its hydrophilicity and low protein adhesion. A PVP target was prepared by pouring 4.0 grams of PVP pellets (K-90, Spectrum Laboratories, Lot#RS0208) in a 1-inch metal die and pressing at 15,000 psi in a Carver press for 30 minutes. The circular target was placed onto a target rotator at the bottom of the coating chamber and a glass slide was fixed on an opposing substrate rotator at the top at a distance of 3 cm from the target. The chamber was purged to 5 Torr and helium introduced into the chamber from below at 200 milliliters per minute for several runs with a resulting pressure of 50 Torr. The coating run was performed at laser energies of 300 mJ/cm² at a pulse rate of 10 hertz for 10 minutes. At the end of the run room air was introduced and the substrate removed. The coated samples were observed using a Olympus BH-1 microscope at 40 to 400 times magnification and 1 to 10 micron thick polymer films were observed. Human 293 human embryonic kidney cells in DMEM media were placed (10⁵ cells per plate) in uncoated (FIG. 8A) and PVP-coated (FIG. 8B) petri dishes and incubated for 3 hours, demonstrating significantly reduced adhesion and spreading of cells onto the PVP-coated sample.

### Example 6

Hydrophobic PTFE Coatings

A coating of poly(tetrafluoroethylene) (PTFE) onto glass slides was produced in accordance with the present invention. Crystalline PTFE has been previously deposited under high vacuum (<1 Torr) using PLD (Heitz, Li et al. 1998). Percutaneous (through the skin) access devices, such as intravenous and peritoneal dialysis catheters, often fail because the lack of tissue bonding leads to the invasion of bacteria and subsequent infection at the access site, leading to removal of the implant and further patient discomfort. In this example, a PTFE target was prepared by pouring 4.0 grams of PTFE powder (Scientific Polymer, Lot#203-07) in a 1-inch metal die and pressing at 15,000 psi in a Carver press for 30 minutes. The circular target was placed onto a target rotator at the bottom of the coating chamber and a glass slide was fixed on an opposing substrate rotator at the top at a distance of 3 cm from the target. The chamber was purged to 5 Torr and helium introduced into the chamber from below at 200 milliliters per minute for several runs with a resulting pressure of 5 Torr. The coating run was performed at laser energies of 300 mJ/cm² at a pulse rate of 40 hertz for 10 minutes. At the end of the run room air was introduced and the substrate removed. Coated glass slides were cured on a hotplate (60 to 120° C.) up to 30 seconds to improve adhesion and produce smooth coatings as previously described (Heitz, Li et al. 1998). One to 10 micron thick polymer films were observed (observed by scratching the coating surface and observing depth of scratch).

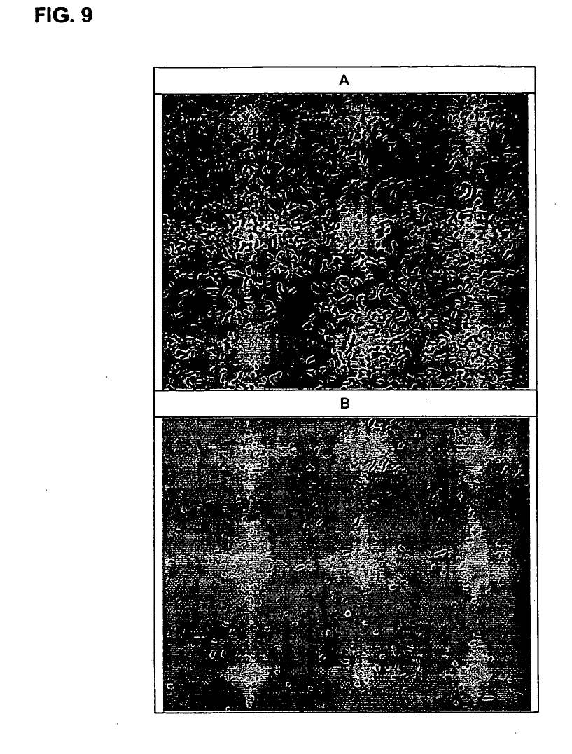

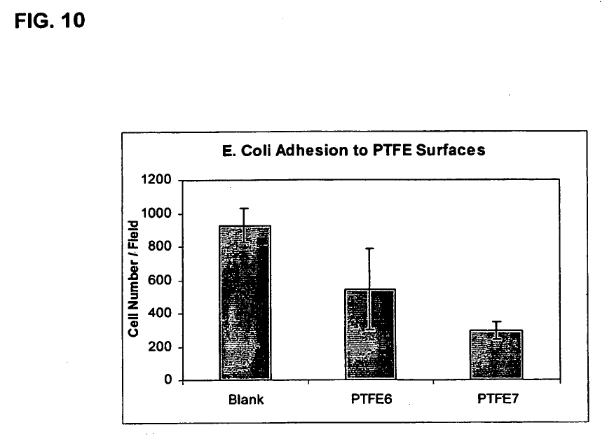

To investigate using PTFE-coatings to reduce bacterial adhesion, E. coli bacteria (DH5a) cells in BHI broth were placed (10⁵ cells per plate) in petri dishes with uncoated (FIG. 9A) and PTFE-coated (FIG. 9B) glass slides and demonstrated significantly reduced adhesion onto PTFE. Cells were counted at 400 times magnification (n=5 each) on uncoated, PTFE-coated with a 15 second cure (PTFE6), and PTFE-coated with a 30 second cure (PTFE7) samples using Scion Image Beta 4.02 for Windows software (Scion Corporation, Frederick, Md.). Statistical significance was measured using a Student T-test comparing both PTFE-coated slides to the uncoated slide (P<0.05) and is displayed in FIG. 10.

### Example 7

Protective PTFE Coatings on Sensors

Protective coatings of poly(tetrafluoroethylene) (PTFE) onto fiber optic fluorescent oxygen probes were also produced in accordance with the present invention. PTFE, also known as Teflon, is a chemically inert polymer and was used to protect a fluorescent oxygen probe (FOXY ⅛″ probe, Ocean Optics, Inc., Dunnelon, Fla.) to organic vapors (jet fuel). Because the fluorescent probe (ruthenium) complexed in a sol-gel matrix cannot withstand organic solvents present in typical dip-coating solutions, solventless application of protective coatings using the described invention were investigated. A Teflon protective coating (over-coating) was applied on the sol-gel coating similar to Example 6 using the multiple substrate holder shown in FIG. 3B. The circular PTFE target was placed onto a target rotator at the bottom of the coating chamber and four oxygen probes (tips coated with fluorescent ruthenium in a sol-gel matrix) were fixed on an opposing substrate rotator at the top at a distance of 3 cm from the target. The chamber was purged to 5 Torr and helium introduced into the chamber from below at 80 milliliters per minute for several runs with a resulting pressure of 5 Torr. The coating run was performed at a laser energy of 500 mJ/cm² at a pulse rate of 40 hertz for 10 minutes. Coated probes were further cured at 60 to 120° C. up to one minute. The probes were then removed and PTFE-overcoated FOXY probes, as well as PDMS-overcoat sol-gel coated probes, were placed in fuel vapor at room temperature and atmospheric pressure (fuel in a test tube). The tube was sealed with parafilm to allow equilibrium between fuel liquid and vapor. The probe was connected to a temperature regulated Ocean Optic spectrometer (TR-SF-2000) designed to provide LED for blue light excitation and CCD array for detecting the spectra of sensor. The fluorescence intensity at 600 nm was monitored vs. time up to 20 hours. A reduction of 15 to 35% was observed with the PTFE-overcoat compared to >80% reduction in signal response for the PDMS-overcoated samples. These experiments suggest that there is significant signal degradation with FOXY coated with silicone when exposed to fuel vapor while lower signal degradation is observed when PTFE is used as an overcoating according to the described invention. PTFE mixed with 5% carbon powder (Alfa) was also deposited successfully as coatings under similar conditions to reduce ambient light effects on fiber-optic probes, and may be further applied to electronic sensors to provide an improved sensor response.

### Example 8

Chemical Attachment of an Enzyme to Functionalized PDMS Coatings

Functionalized coatings of poly(dimethyl siloxane) (PDMS) were produced onto similar square PDMS samples for chemical attachment of an enzyme according to the present invention under similar conditions as Example 1. Biocatalytic coatings of hydrolytic enzymes with PDMS have been previously proposed using sol-gel entrapment and covalent attachment for paints (Kim, Dordick et al. 2001). Silicone, which is currently used in urological stents (Wironen, Marotta et al. 1997), produces a nucleation site for oxalate crystal formation after implantation, so attachment of oxalate degrading enzymes was investigated. Silicone elastomer (MDX4-4210, medical grade elastomer, Dow Corning, Midland, Mich., supplied by Factor II, Inc., Lakeside, Ariz.) films were prepared following the manufacturer's instructions. Briefly, the elastomer was cast into 2 mm thick sheets by curing the resin between acrylic plates separated by a 2 mm spacer. The prepared sheets were allowed to cure for 48 hours at room temperature and disks were cut from the cured sheets using a cork-boring tool (Boekel, Feasterville, Pa.), and further extracted for 48 hours in HPLC grade hexane to remove the low molecular weight and unreacted species and then dried under vacuum. A circular target was placed onto a target rotator at the bottom of the coating chamber and square PDMS substrate was fixed on an opposing substrate rotator at the top at a distance of 3 cm from the target. The chamber was purged to 5 Torr and helium introduced into the chamber from below at 100 milliliters per minute with a resulting pressure of 5 Torr. The coating run was at laser energy of 450 mJ/cm² at a pulse rate of 10 hertz for 10 minutes, producing a white spot. The modified PDMS sample was then reacted with a solution of 2% 3-aminopropyltriethoxysilane (AMEO, Sigma) in 95% ethanol for 1 hour and then rinsed with 100% ethanol for 15 minutes. Uncoated PDMS samples were compared to PLD-coated PDMS samples, as well as with radio frequency plasma discharge (RFPD) modified samples, for changes in surface properties and chemical attachment of oxalate enzymes.

Captive air contact angle measurements for untreated, RF plasma treated, and PLD coated silicone elastomer disks (PDMS) were performed. In general, surface modification by either RFPD or PLASF resulted in a more hydrophilic surface. While plasma treatment with aqueous ammonia and H₂O vapor-AMEO resulted in surface hydrophobicity similar to that of the control (untreated) surface, other RFPD treatments resulted in markedly lower contact angles. PLD treatment produced a very hydrophilic surface, as indicated by an immeasurable contact angle prior to AMEO coating. Upon PLD-AMEO coating, the contact angle increased, resulting in hydrophilicity similar to that measured on the hydrophilic plasma treated surfaces. XPS analysis also showed the surface of the modified silicone elastomer, via RFPD or PLD, an increase in oxygen content and concomitant decreased carbon content, while the silicon content remained essentially unchanged. Studies showed that the PLD-coated silicone surface deposition followed by AMEO functionalization resulted in a slightly greater increase in surface nitrogen content compared to H₂O/AMEO plasma treatment, indicating a higher level of AMEO attachment. Finally, FTIR also showed a greater change in surface composition compared to plasma modification.

Oxalate-degrading enzyme was then covalently bound to the RFPD and PLD surface-modified silicone elastomer samples through glutaraldehyde bioconjugation. The surface-modified silicone disks were placed into separate wells of a 24-well tissue culture plate (Corning Costar; Fisher Scientific Co., Pittsburgh, Pa.). The disks were washed twice (5 min. each) with 0.01 M phosphate buffered saline (PBS) pH 7.4 on a rocker with slight agitation. A 2.5% glutaraldehyde solution (Sigma Chemical Co., St. Louis, Mo.), in 0.01 M PBS, was added to each disk, and the plate was incubated for 1 hour at room temperature, with slight agitation. The disks were subsequently washed 3 times with PBS (5 min. each), followed by two washes (5 min. each) with buffer appropriate for each enzyme. Oxalate oxidase (OXO) was obtained from Sigma Chemical Co., St. Louis, Mo., and oxalate decarboxylase (OXD) was produced at Ixion Biotechnology (Alachua, Fla.). Disks were then transferred to clean tissue culture plates. To each disk, 1 ml of the 100 mg/ml OXO and OXD oxalate-degrading enzymes in solution, prepared in its appropriate buffer, was added. The same amount of enzyme was added to a well with no disk, which served as a positive control for enzyme activity analysis. The tissue culture plate was incubated on a rocker at 4° C. for 48 hours at 20 rpm. Following incubation, the enzyme solution was aspirated and the disks were washed with appropriate buffer (5 min per wash). The amount of immobilized enzyme, extrapolated from a standard curve of BSA solutions, was about 24 mg of enzyme protein immobilized on an aminated 10 mm diameter silicone elastomer disk via glutaraldehyde bioconjugation. For oxalate oxidase experiments activity was determined in terms of hydrogen peroxide produced and oxalate decarboxylase activity was measured from formate generated by formate dehydrogenase. Although both oxalate oxidase and oxalate decarboxylase could be successfully immobilized on both modified elastomer surfaces, the immobilized oxalate decarboxylase attached to PLD surfaces retained significantly higher enzymatic activity (784 U/mg protein compared to 0.038 U/mg protein for plasma modified). Thus, from the described experiments it was concluded that the PLD surface modification resulted in better surface functionalization than radiofrequency plasma treatment (RFPD). The results also provide an indication that, although the same amount of protein can be bound after PLD or RFPD treatment, PLD treatment maintains the functionality of the bound protein better than RFPD treatment.

### Example 9

Chemoselective PECH and PIB Polymer Coatings

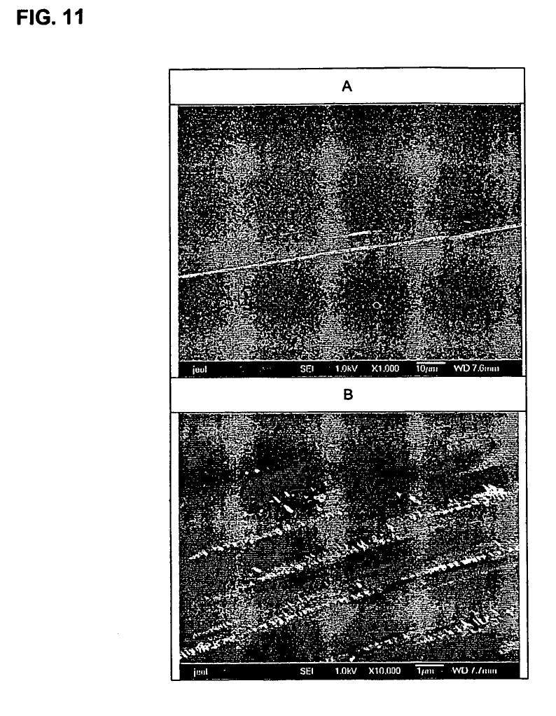

Coatings of poly(epi-chloro-hydrin) (PECH) and poly(iso-butylene) (PIB) onto silicon wafers were also produced in accordance with the present invention. PECH and PIB are chemoselective coatings used in vapor sensors for detecting explosives (Houser, Mlsna et al. 2001). PECH (Scientific Polymer, Lot#127-06) and PIB (Scientific Polymer, Lot#682-03) targets were cut from block polymer samples to obtain approximately 1-inch circular samples. The circular target was placed onto a target rotator at the bottom of the coating chamber and a glass slide was fixed on an opposing substrate rotator at the top at a distance of 3 cm from the target. The chamber was purged to 5 Torr and helium introduced into the chamber from below at 200 milliliters per minute for several runs with a resulting pressure of 5 Torr. The coating run was performed at laser energies of 150 to 600 mJ/cm² at a pulse rate of 10 to 40 hertz for 10 minutes. At the end of the run room air was introduced and the substrate removed. The coated samples were observed using a Jeol model 6330 Cold-Field Emission Gun Scanning Electron Microscope (SEM) to obtain information on the thickness and surface morphology of coatings. Micrographs of films were prepared by placing coated silica wafers onto a graphite sample mount without sputter coating. Characterization was performed at 1 keV in vacuum and analyzed at 1,000 to 20,000 times magnifications. SEM photomicrographs of PIB and PECH-coated silicon wafers are shown in FIGS. 11A and 11B, respectively, at 1,000 and 10,000 times magnification. Coating thicknesses were not quantitative, but there appeared to be a substantial improvement in nanometer-level thickness control and morphology. Atomic force microscopy, using a Digital Nanoscope 3 atomic force microscope (AFM) in tapping mode at 1 to 10 micron scan areas and 1 to 4 Hz tapping frequencies, of PIB-coated silicon wafers also show a substantial improvement in coating morphology control compared to coatings without gas-assist. High resolution AFM images show RMS roughnesses from 1 to 2 nanometers, which has been shown to translate to improved SAW-sensor signal robustness for gas and microfluidic sensor applications.

### CITED DOCUMENTS

Chang, T. and P. Molian (1999). “Excimer pulsed laser ablation of polymers in air and liquids for micromachining applications.” Journal of Manufacturing Processes 1(1): 1-17.
Coon, J. J. and W. W. Harrison (2002). “Laser desorption-atmospheric pressure chemical ionization mass spectrometry for the analysis of peptides from aqueous solutions.” Anal Chem 74(21): 5600-5.
Coon, J. J., K. J. McHale, et al. (2002). “Atmospheric pressure laser desorption/chemical ionization mass spectrometry: a new ionization method based on existing themes.” Rapid Commun Mass Spectrom 16(7):681-5.
Cotell, C., D. Chrisey, et al. (1993). Laser-deposited biocompatible films and methods and apparatuses for producing same. USA, The United States of America as represented by the Secretary of the Navy.
Goldberg, E., J. Burns, et al. (1989). Ocular implants and methods for their manufacture. USA, University of Florida.
Heitz, J., S. Li, et al. (1998). “Pulsed-laser deposition of crystalline Teflon (PTFE) films.” Applied Surface Science 125(1).
Higuchi, A., K. Shirano, et al. (2002). “Chemically modified polysulfone hollow fibers with vinylpyrrolidone having improved blood compatibility.”.
Houser, E., T. Mlsna, et al. (2001). “Rational materials design of sorbent coatings for explosives: applications with chemical sensors.” Talanta 54(3): 469485.
Kim, Y., J. Dordick, et al. (2001). “Siloxane-based biocatalytic films and paints for use as reactive coatings.” Biotechnol Bioeng 72(4): 475-82.
Mombelli, A., B. Schmid, et al. (2002). “Local antibiotic therapy guided by microbiological diagnosis.” J Clin Periodontol 29(8): 743-9.
Moussy, F., D. Kreutzer, et al. (2002). Implant coating for control of tissue/implant interactions. USA, The University of Connecticut.
Narayanan, P., S. Rowland, et al. (1994). Treatment of metallic surfaces using radiofrequency plasma deposition and chemical attachment of bioactive agents. USA, Cordis Corporation.
Norkiewicz, D. S., L. G. Breault, et al. (2001). “The use of chemotherapeutic agents in localized periodontal pockets.”.
Pataro, A. L., C. F. Franco, et al. (2003). “Surface effects and desorption of tetracycline supramolecular complex on bovine dentine.” Biomaterials 24(6): 1075-80.
Ruckenstein, E. and S. V. Gourisankar (1986). “Preparation and characterization of thin film surface coatings for biological environments.” Biomaterials 7(6): 403-22.
Webber, W. L., F. Lago, et al. (1998). “Characterization of soluble, salt-loaded, degradable PLGA films and their release of tetracycline.” J Biomed Mater Res 41(1): 18-29.
Weng, J., M. Wang, et al. (2002). “Plasma-sprayed calcium phosphate particles with high bioactivity and their use in bioactive scaffolds.” Biomaterials 23(13): 2623-9.
Whitlock, R. and G. Frick (1994). “Particle size distributions of aerosols formed by laser ablation of solids at 760 Torr.” Journal of Materials Research 9(11): 2868-2872.
Wironen, J., J. Marotta, et al. (1997). “Materials used in urological devices.” J Long Term Eff Med Implants 7(1): 1-28.
Zabetakis, P., C. Cotell, et al. (1995). Medical device with infection preventing feature. USA, The United States of America as represented by the Secretary of the Navy.

What is claimed is:

1. A method of coating a substrate surface, comprising:
providing a target material;
providing a substrate;
ablating said target material to form ablated target particulate material;
directing the ablated target particulate material with a gas flow;
and coating said substrate surface with said ablated target particulate material to form a coated substrate.

2. The method of claim 1, wherein the coating occurs at a pressure of about 1 Torr or higher.

3. The method of claim 2, wherein the coating occurs at a pressure of about 760 Torr.

4. The method of claim 1, wherein the gas flow is directed at the substrate at a flow rate of about 1 milliliter per minute or higher, and at a velocity sufficient to direct the ablated particulate material toward the substrate.

5. The method of claim 2, wherein the gas flow is directed at the substrate at a flow rate of about 10 milliliters per minute or higher.

6. The method of coating a substrate according to claim 1, wherein the target material comprises at least one of biodegradable polymers, biocompatible polymers, chemoselective polymers, polysaccharides, and proteins.

7. The method of coating a substrate according to claim 1, wherein said ablating is achieved by the use of a high-energy source.

8. The method of coating a substrate according to claim 7, wherein the high-energy source is a laser selected from ion laser, diode array laser, and pulsed excimer laser.

9. The method of claim 1, wherein coating said substrate material with said ablated particulate target material results in a coating on the substrate having a thickness of less than about 1 mm.

10. The method of claim 9, wherein said coating on the substrate has a thickness of less than about 0.1 mm.

11. The method of claim 10, wherein said coating on the substrate has a thickness of less than about 0.01 mm.

12. The method of claim 1, wherein said substrate comprises at least one surface of a biomedical device selected from the group consisting of electronic gas sensors, acoustic gas sensors, microfluidic biosensors, microarrays, at least partially implanted devices, or external devices in contact with biological fluids and/or surfaces.

13. The method of claim 12, wherein said substrate is a biomedical device selected from stents, catheters, vascular grafts, contact lenses, ocular implants, oral implants, hip implants, pacemakers, defibrillators, and bone fixation devices.

14. The method of claim 12, wherein said substrate is a sensor device selected from metal-oxide sensors, conducting polymer sensors, electrochemical sensors, fiber-optic fluorescent sensors, and surface acoustic wave sensors.

15. The method of claim 1, wherein said coating of the target material on the substrate results in a continuous coating.

16. The method of claim 1, wherein said coating of the target material on the substrate results in a discontinuous coating.

17. The method of claim 1, wherein the gas flow is directed away from the substrate at a flow rate of about 1 milliliter per minute or higher, and at a velocity sufficient to decrease the rate of deposition of the ablated particulate material on the substrate.

18. A coated substrate formed according to the method of claim 1.

19. A method of coating a substrate surface, comprising:
providing a target material;
providing a substrate;
ablating said target material to form ablated target particulate material;
directing the ablated target particulate material toward the substrate with a gas flow;
and coating said substrate surface with said ablated target particulate material to form a coated substrate;
wherein the coating occurs at a pressure of about 1 Torr or higher;
and wherein the coating results in a coating thickness on the substrate less than about 1 mm.

20. A coating apparatus comprising:
a coating chamber housing a target material in its interior;
the chamber comprising a transparent window;
a target evaporation source exterior to the coating chamber;
a means for directing a gas flow toward the substrate.
